(19) United States
(12) Patent Application Publication
(10) Pub. No.: US 2026/0217018 A1
(43) Pub. Date: Jul. 30, 2026

(54) DEVICE AND METHOD FOR PROCESSING A SUBSTRATE IN AN EVACUATED PROCESSING SPACE

(71) Applicant: EV GROUP E. THALLNER GMBH, St. Florian am Inn (AT)

(72) Inventor: Martin EIBELHUBER, St. Florian am Inn (AT)

(73) Assignee: EV GROUP E. THALLNER GMBH, St. Florian am Inn (AT)

(21) Appl. No.: 19/141,439

(22) PCT Filed: Jan. 3, 2023
(86) PCT No.: PCT/EP2023/050054

§ 371 Date: Jun. 20, 2025

(51) Int. Cl. B41F 19/02

(52) U.S. Cl. CPC B41F 19/02

(57) ABSTRACT

A device and a method for the processing, in particular nano-embossing, of a substrate in a local and fluidically tight processing space is disclosed.

### RELATED APPLICATION

This application is a national stage of International Application No. PCT/EP2023/050054, filed Jan. 3, 2023, which is hereby incorporated herewith in its entirety.

### FIELD OF THE INVENTION

The present invention relates to a method and a device for the processing of substrates. In particular, the invention relates to a method and a device for the embossing, in particular the nano-embossing, of substrates with improved alignment.

### BACKGROUND OF THE INVENTION

The processing of substrates is advantageous in a vacuum in several processing methods in the prior art. For this purpose, the entire device or at least the corresponding module often has to be evacuated. In particular, the long evacuation process is a drawback, since the productivity falls due to frequent and long evacuation. The processing of the substrate in a vacuum is often necessary in order to prevent embossing errors, in particular air inclusions.

The invention particularly relates to a method and a device for UV-NIL imprinting, wherein structures, in particular nanostructures, can be produced with a soft nanostructure stamp, in particular a flexible film stamp.

Nanoimprint lithography (NIL) is a moulding process, in which micro-and/or nanostructures are moulded by a stamp into curable materials, e.g. lacquer. Moulding of a large number of nanostructure systems is possible.

In principle, a distinction is made between thermal NIL (hot-embossing NIL) and UV-based NIL processes. In UV-NIL, the stamp is pressed at room temperature into a flowable lacquer. On account of the viscosity of the photoresist lacquer, the intermediate spaces of the stamp are thus completely filled by the capillary effect. The UV lacquer crosslinks with the exposure to UV radiation to form a stable polymer (curing).

The structuring with soft polymer stamps has a number of advantages compared with hard stamps. The reason is to be found in the easy production of the stamps, efficient embossing processes, very good surface properties of the respective stamp materials, the low cost, the reproducibility of the embossed product and above all the possibility of the elastic deformation of the stamp during the demoulding.

The production of high-precision nanostructures on large areas can be carried out by a roller process without a vacuum (SmartNIL). In WO2014/037044A1, a method and a device are described, in which a micro-and/or nano-structured stamp, in particular a flexibly constituted film stamp, and a frame are used. In addition, the structures from the film stamp from WO2014/037044A1 have to be pressed by the embossing element, in particular a rigid embossing roller, into the embossing material.

In publication WO2015/161868A1, prestressing is applied to a nanostructured stamp before the contacting. The prestressing is achieved by a deformation of the nanostructured stamp by means of deformation means. Positioning inaccuracies and further embossing errors can thus make the embossing result worse.

The device from WO2015/161868A1 can also be operated in a vacuum, wherein the entire device must be evacuated. The embossing stamp is not a flexible, soft film stamp stretched across a film frame, but rather a hard polymer stamp.

It is the object of the invention, therefore, to eliminate at least partially, in particular completely eliminate, the drawbacks listed in the prior art. In particular, it is an object of the invention to specify an improved method and an improved device for the processing, in particular embossing of substrates.

### SUMMARY OF THE INVENTION

The object of the invention is achieved with the features of the coordinated claims. Advantageous developments of the invention are given in the sub-claims. All combinations of at least two features indicated in the description, in the claims and/or the drawings fall within the scope of the invention. In the case of stated value ranges, values also lying within the stated limits should be deemed to be disclosed as limiting values and can be claimed in any combination.

Accordingly, the invention relates to a method for the processing, in particular the nano-embossing, of a substrate with at least the following steps: a) provision of a substrate mounting arrangement for mounting the substrate, b) provision of a device for processing the substrate, c) formation of a local and fluidically tight processing space between the substrate mounting arrangement and the device, d) evacuation of the processing space and e) processing of the substrate, wherein the evacuation in step d) takes place after the formation of the processing space in step c).

Instead of a substrate, a substrate stack can also be processed. In the following. the method and the device will be described in connection with a substrate, but a substrate stack can also be correspondingly processed. The processing can also comprise a two-sided processing of the substrate, wherein a multiple or a triple stack arrangement, i.e. triple stack, can be used. For example, a substrate can be embossed on both sides.

Advantageously, therefore, a processing space can be formed which is local or much smaller than the space around the device. The processing space is at least partially formed or sealed by the device and the substrate mounting arrangement. In other words, a spatially demarcated processing space can be formed around the substrate. Due to the small volume, the latter can be evacuated particularly quickly and efficiently.

The evacuation takes place by means for evacuation, which are arranged on the substrate mounting arrangement and/or the device, in such a way that, after the formation of the processing space, the latter can be evacuated. The substrate is arranged inside the processing space. The processing takes place in the processing space, whereby the latter is at least partially evacuated.

In a preferred embodiment of the method for the processing, provision is made such that the formation of the processing space takes place by an approach of the substrate mounting arrangement and the device, wherein the device and the substrate mounting arrangement are aligned with one another before the approach.

In the course of the alignment and/or the approach, the substrate mounting arrangement and the device are aligned with one another, in such a way that optimum processing and an optimum processing result is enabled. An exact alignment is necessary especially for embossing or bonding processes. As a result of the alignment of the substrate mounting arrangement and the device with one another, the substrate can also advantageously be aligned or arranged precisely.

The substrate is fixed in the substrate mounting arrangement preferably with fixing elements. The approach and the alignment take place preferably by means of actuators or other means for the alignment or approach. The alignment and the approach in step c) can also be carried out in a different sequence. It is conceivable that the alignment is first carried out and then an approach of the substrate mounting arrangement and the device. After the approach and the formation of the processing space, the alignment of the substrate or the processing means can also take place. A parallel execution of the approach and the alignment is also conceivable.

By means of the approach of the substrate mounting arrangement and the device, a local and fluidically tight processing space is created around the substrate. This processing space is evacuable and is constituted at least partially between two mounting arrangement. The processing space can also be constituted in part by the seals, which are preferably fixed at least to the substrate mounting arrangements. A part of the substrate mounting arrangement or the device can also in each case form the seals. A sealing ring is preferably used for the sealing or the formation of the processing space.

Due to the fact that the alignment and approach is carried out before the evacuation, a local evacuation can advantageously then take place, wherein alignment errors are prevented. In addition, only the local processing space can advantageously be evacuated. An evacuation of the device and of the entire module is thus not necessary. In this way, a particularly rapid and efficient processing of the substrate is possible.

In a preferred embodiment of the method for the processing, provision is made such that the formation of the processing space takes place by controllable sealing means. In other words, no approach takes place for the formation of the processing space, but rather it is sealed by the sealing means of the processing space. The substrate can for example be loaded from the side, so that the structure of the device can be designed particularly small. Advantageously, only a small space thus has to be evacuated, so that the processing time can be reduced.

In a preferred embodiment of the method for the processing, provision is made such that the device comprises a flexible film stamp for the processing, in particular for the embossing, of the substrate and in which, during the processing of the substrate, a fluidically tight flushing space between the device and the film stamp is flushed for curving the film stamp, wherein the processing space and the flushing space are separated from one another fluidically by the film stamp. In other words, two different pressure areas are formed in the device, which are separated from one another fluidically by the film stamp, so that the film stamp can be deformed in a targeted manner for embossing and demoulding by the pressure differences. The flushing space is flushed by flushing means, which can at the same time be constituted as evacuation means, so that the film stamp is curved or bent in the direction of the substrate. The embossing force or deformation of the film stamp can advantageously be adjusted by the pressure difference. In addition, the demoulding after the processing or embossing can advantageously take place gently and be supported by a reduction in the pressure difference. The pressure in the processing space can also be adapted accordingly.

The flushing space is at least partially formed first by flushing with a fluid by the flushing means, since the film stamp abuts directly against a section of the device and/or a film frame. However, it is also conceivable that a part of the flushing space is already constituted on account of the construction of the film frame or the device and this flushing space is further enlarged by the flushing. The film stamp seals the flushing space from the processing space. In this way, particularly gentle and error-free embossing, in particular nano-embossing, is possible.

In a preferred embodiment of the method for the processing, provision is made such that a pressure difference between the pressure of the processing space and the flushing space is set between 0 and 800 mbar, more preferably between 100 and 600 mbar, still more preferably between 200 and 600 mbar for the processing, in particular the embossing. In other words, the prevailing pressure in the processing space and the prevailing pressure in the flushing space are regulated in such a way that a desired embossing force and deformation of the film stamp is brought about. A pressure difference in the aforementioned regions has proved to be particularly advantageous in tests.

In a preferred embodiment of the method for the processing, provision is made such that the substrate is aligned relative to processing means of the device in the constituted processing space. The processing means can for example be embossing means, bonding or debonding means or any processing means, with which a precise relative alignment with the substrate is advantageous. Due to the fact that the substrate is aligned relative to the processing means of the device during the alignment, a particularly precise alignment is possible before the evacuation. An indirect alignment of the substrate with the processing means is also conceivable by an alignment of the substrate mounting arrangement or the device, wherein alignment marks are preferably used.

In a preferred embodiment of the method for the processing, provision is made such that the alignment of the substrate is carried out at normal pressure. In other words, the evacuation only takes place after the alignment of the substrate and after the formation of the processing space. Normal pressure is the pressure prevailing in the device under normal circumstances. When the device is loaded with the substrate at ambient pressure, it is in particular the prevailing atmospheric pressure. The approach also takes place at the normal pressure. The method for processing can thus take place particularly efficiently. In addition, an alignment can be carried out particularly precisely at normal pressure.

In a preferred embodiment of the method for the processing, provision is made such that the substrate is released during the processing in step e). The substrate can then freely interact with the processing means during the processing in the evacuated processing space. In this way, a particularly good processing result can be achieved with embossing processes for example.

In a preferred embodiment of the method for the processing, provision is made such that the processing in step c) comprises complete contacting of the substrate with the film stamp. The substrate is thus embossed or contacted with the embossing stamp in the evacuated processing space. For example, a lacquer previously applied on the embossing stamp can be received in structures, preferably nanostructures, on the substrate or can be embossed into a specific structure in the substrate. The embossing stamp is flexible and can lie particularly freely on the substrate, so that embossing in the evacuated processing space can take place particularly precisely and freely. The substrate and the embossing stamp completely abut against one another, so that complete embossing is possible.

In a preferred embodiment of the method for the processing, provision is made such that the film stamp in the processing in step e), after complete contacting with the substrate, is at least partially released, so that the film stamp can relax against the substrate. In the local and evacuated processing space, the flexible film stamp is thus at least partially raised or moved after the complete contacting, in such a way that a particularly free relaxation of the film stamp against the substrate can take place. For this purpose, the film stamp is preferably deformed or released by the flushing means. The flushing means are in particular arranged on a rear side of the film stamp facing away from the substrate, so that during flushing with a fluid a slight overpressure arises relative to the pressure otherwise prevailing in the evacuated processing space, so that the film stamp is released from a holding surface. The film stamp does not have to abut against the film mounting arrangement. Flooding of the entire processing space is preferably not carried out by the flushing means, but a small overpressure for the release of the film stamp is only produced in the region of the rear side of the film stamp. In this way, a particularly precise and gentle embossing can take place in the processing space. In this embodiment of the method for the processing and embossing, provision is made such that two pressure zones are present and the latter are separated by the film stamp. The processing space is fluidically separated in the region of the rear side of the film stamp, in particular by the film stamp itself, from the remaining region of the processing space. A first pressure zone is defined by the formation of the processing space, which can be evacuated. A second pressure zone is located in the region of the rear side of the film stamp (flushing zone). This second pressure zone can be flooded by a flushing agent.

In a preferred embodiment of the method for the processing, provision is made such that a film frame for accommodating the film stamp continues to remain fixed in the device. The film stamp is preferably fixed or stretched on a film frame. The film frame can thus be fixed independently of the film stamp on the film mounting arrangement and advantageously remains fixed when a release or flushing takes place. In this way, the film stamp remains fixed on the frame in a preferred embossing position, wherein the film stamp can nonetheless abut particularly well against the substrate. In other words, the film stamp can relax particularly well against the substrate with further fixing of the frame.

In a preferred embodiment of the method for the processing, provision is made such that the flushing means also increase the pressure in the flushing space during the processing, so that an embossing force for embossing the substrate can be adjusted. Particularly preferably, the pressure in the processing space is kept constant. The film stamp can thus contact or emboss the substrate particularly uniformly and gently. The film stamp can thus relax against the substrate. In the embossing process, the filling of the structures of the film stamp by capillary forces is additionally supported by the (slight) rear-side overpressure in the flushing space.

In a preferred embodiment of the method for the processing, provision is made such that the pressure difference between the pressure of the processing space and the pressure of the flushing space is used for the demoulding of the film stamp from the substrate. The pressure in the processing space is preferably kept constant. In other words, the film stamp can advantageously be pulled back from the embossing compound by a reduction of the pressure in the flushing space or an evacuation.

In a preferred embodiment of the method for the processing, provision is made such that the device is constituted in such a way that a control of embossing and demoulding takes place in an automated manner by a pressure regulation of the pressure of the processing space and the pressure of the flushing space. The arising pressure difference between the two pressure zones is used to produce external forces, which act on the film stamp, during embossing and demoulding.

Furthermore, the invention relates to a device for the processing of a substrate, comprising at least i) a substrate mounting arrangement for the mounting of the substrate, ii) a device for processing the substrate, iii) means for the formation of a local and fluidically tight processing space between the substrate mounting arrangement and the device, iv) evacuation means for evacuating the processing space and v) processing means for processing the substrate.

The aforementioned advantages and features of the method for the processing of a substrate similarly apply correspondingly to the device. The device is preferably constituted in order that an evacuation of the constituted processing space can be carried out by the evacuation means only after alignment. The processing space is at least partially, preferably completely, arranged between the substrate mounting arrangement and the device.

The processing means are at least partially arranged in the processing space or can act on the substrate in the processing space. The processing space is evacuated during processing. The processing means can in particular be means for embossing, means for bonding or debonding as well as means for laser processing or other means. In addition, the processing means can also at least partially constitute the sealing means. In this way, particularly efficient processing of the substrate in the processing space is possible.

The device is preferably constituted in such a way that the substrate can be released. The device thus permits a particularly precise alignment and processing of the substrate in the processing space. The device is thus predestined for an efficient and precise processing of a substrate or a substrate stack in a vacuum, in particular for the nano-embossing of substrates.

In a preferred embodiment of the device for the processing of substrates, provision is made such that the means are approach means for the approach of the substrate mounting arrangement and the device. In other words, the processing space is advantageously formed quickly and directly by a relative movement of the device and/or the substrate mounting arrangement. In this way, a local processing space can be formed between the two components.

In a preferred embodiment of the device for the processing of substrates, provision is made such that the device also comprises alignment means for the alignment of the substrate mounting arrangement and the device with one another, wherein the alignment means is constituted such that the substrate mounting arrangement and the device can be aligned with one another before and/or during an action of the approach means. The alignment can also comprise an adjustment. In this way, the processing space can be constituted precisely. In addition, an alignment of the substrate with the processing means can advantageously take place at the same time by means of the alignment means. The fine alignment of the substrate after the formation of the processing space can also take place as required.

During the alignment and/or the approach, the substrate mounting arrangement and the device are aligned with one another, in such a way that optimum processing and an optimum processing result is enabled. In particular, an exact alignment is necessary for embossing and bonding processes. By means of an alignment of the substrate mounting arrangement and the device with one another, the substrate can also be advantageously aligned or arranged precisely.

The substrate is fixed in the substrate mounting arrangement preferably with fixing elements. The approach and the alignment take place for example by actuators. The alignment and the approach can also be carried out in a different sequence. It is also conceivable for the substrate mounting arrangement and the device to be first aligned and then an approach. After the approach and the formation of the processing space, an alignment can also take place. A parallel execution of the approach and the alignment is also conceivable.

As a result of the approach of the substrate mounting arrangement and the device, a local and fluidically tight processing space is created around the substrate. This processing space can be evacuated and at least partially formed between the two mounting arrangements. The processing space can be formed by seals, which are preferably affixed at least to the substrate mounting arrangement. In each case, a part of the substrate mounting arrangement or the device can also constitute the seals. A sealing ring is preferably used for the sealing or formation of the processing space. If the seals are formed on the substrate mounting arrangement and on the device, it preferably involves corresponding sealing elements.

Due to the fact that the alignment and approach is carried out before the evacuation, an evacuation can advantageously be carried out thereafter, wherein alignment errors are prevented. In addition, only the local processing space can advantageously be evacuated. An evacuation of the device or the entire module is thus not necessary. In this way, a particularly quick and efficient processing of the substrate is possible.

In a preferred embodiment of the device for the processing of substrates, provision is made such that the substrate mounting arrangement and the device comprises corresponding sealing means, wherein the approach means are constituted such that, after the action of the approach means, the corresponding sealing means form the processing space between the substrate mounting arrangement and the device. In other words, a part of the processing space is formed by the sealing means. The sealing means can be constituted in such a way that, for example, engagement into one another at several points is possible, so that in this way the substrate can thus be aligned advantageously with the processing means at the same time. The processing space can thus be constituted advantageously in different positions of the device and the substrate mounting arrangement.

In a preferred embodiment of the device for the processing of substrates, provision is made such that the means are controllable sealing means for the formation of the processing space between the substrate mounting arrangement and the device. A direct approach of the device and the substrate mounting arrangement does not therefore take place. On the contrary, the space between the device and the substrate mounting arrangement is sealed by the sealing means and the processing space is thus formed. In this way, the processing space can advantageously be formed quickly and efficiently. In addition, an alignment of the substrate mounting arrangement and the device with one another can be omitted or can take place beforehand.

In a preferred embodiment of the device for the processing of substrates, provision is made such that the substrate mounting arrangement and the device are constituted in one piece. A particularly compact structure of the device is thus enabled. In addition, an alignment of the substrate with respect to the processing means can also be dispensed with by the one-piece embodiment or can already take place when the device is loaded with the substrate, preferably by sliding in the substrate from the side or parallel to the mounting surface of the substrate mounting arrangement. Positioning errors are thus prevented and a processing space with a particularly small volume is provided for the efficient formation of a vacuum.

In a preferred embodiment of the device for the processing of substrates, provision is made such that the processing means comprises a flexible film stamp for the embossing, in particular the nano-embossing, of the substrate. A flexible film stamp is predestined for the use in the device. The film stamp can be provided in a film frame. The film stamp particularly preferably forms a part of the processing space or an outer edge.

In a preferred embodiment of the device for the processing of substrates, provision is made such that the device additionally comprises flushing means for the formation of a fluidically tight flushing space between the device and the film stamp, wherein the flushing space is separated fluidically by the film stamp from the processing space, and wherein the film stamp is deformed by the flushing means in a targeted manner. The flushing means are for example valves, via which the flushing space can be flooded or evacuated. In other words, the pressure can be adjusted by the corresponding amount of fluid on the side of the film stamp facing away from the processing space, so that the film stamp can be deformed in a targeted manner or curved in the direction of the substrate. The flushing space is at least partially formed by the film stamp. The device itself or partially a film frame can also define the flushing space. The film stamp can first abut with the side facing away from the processing space against the device or a film frame, so that the flushing space is not formed until the introduction of a fluid by the flushing means. It is also conceivable that a part of the flushing space is already provided by the geometry of the device and/or the film frame. In this case, the flushing space is enlarged by the flushing means, wherein the film stamp is deformed in the direction of the substrate. In this way, particularly gentle and error-free embossing is possible.

In a preferred embodiment of the device for the processing of substrates, provision is made such that the device is constituted so that a pressure difference between the pressure of the processing space and the flushing space can be set between 0 and 800 mbar, preferably between 100 and 600 mbar, still more preferably between 200 and 600 mbar. In other words, a pressure difference is set in the aforementioned regions in order to adjust the deformation and the embossing force in a targeted manner. This pressure difference is preferably regulated by the flushing means in dependence on a constant pressure in the processing space. In this way, the embossing process can advantageously be initiated by the flushing means.

In a preferred embodiment of the device for the processing of substrates, provision is made such that the flushing means are at the same time evacuation means, so that the film stamp can be demoulded from the substrate by evacuation of the flushing space. In other words, the embossing force can be reduced and the deformation during the embossing can be reduced by an evacuation of the flushing space by the flushing means. In this way, demoulding of the film stamp from the substrate or an embossing material provided thereon can advantageously be carried out in a gentle manner after the embossing.

The pressure in the region of the rear side of the film stamp or in the flushing space is set between 1 mbar and 1500 mbar, preferably between 1100 mbar and 1250 mbar.

In a preferred embodiment, a rough vacuum is adjusted between the film stamp and the substrate in the processing space after the alignment.

During the evacuation, the pressure in the embossing space is less than 500 mbar, preferably less than 300 mbar, most preferably less than 250 mbar.

In particular, a rough vacuum is preferably set between 300 mbar and 1 mbar, most preferably between 250 mbar and 100 mbar. In a preferred embodiment, in addition to the rough vacuum in the embossing space, the pressure is set in the region of the rear side of the film stamp (flushing zone) preferably between 1100 mbar and 1250 mbar during and/or after the (complete) contacting between the film stamp and the substrate coated with the embossing compound.

The pressure difference between the processing space and the region of the rear side of the film stamp (flushing zone) or the flushing space is also used for demoulding the film stamp from the embossing compound. For this purpose, the pressure in the processing space is set to normal pressure, whereas the pressure in the region of the rear side of the film stamp (flushing zone) for example to between 1100 mbar and 1500 mbar.

In a preferred embodiment of the device for the processing of substrates, provision is made such that the pressure difference between the processing space and the rear side of the film stamp is used for the active control of the embossing and the demoulding. External forces are thus generated, which are used for the processing of the substrate. The range of the generated forces, in particular embossing forces, preferably lies between 100 N and 10 kN.

In a preferred embodiment of the device for the processing of substrates, provision is made such that the processing space between the substrate mounting arrangement and the device can be constituted in the region of the substrate, in such a way that the substrate can be completely arranged inside the processing space. In this way, wafers standard in the trade and other semiconductor elements can in particular be efficiently processed in the processing space.

In an embodiment of the device for the processing of substrates, provision is made such that the processing means comprises means for bonding, preferably for the bonding of flexible substrates and/or film substrates, which are fixed on film frames. In this way, particularly efficient processing of the substrate in the processing space is possible by flexible joining and contacting in the bonding. For example, electronic and/or optical components, in particular chips or dies, which are applied on a thin (carrier) substrate, can be bonded with a second substrate, in particular a wafer, i.e. chip-to-wafer bonding.

In a preferred embodiment of the device for the processing of substrates, provision is made such that the processing means comprise embossing means, preferably a flexible embossing stamp, for embossing the substrate. The device is predestined for particularly precise and efficient embossing in a vacuum. The flexible embossing stamp is a soft stamp. The embossing stamp can itself comprise structures, which are transferred onto the substrate or are moulded on the substrate. In addition, the flexible embossing stamp can also apply lacquers or other materials on the substrate. Especially in a vacuum, the embossing with embossing means can be carried out particularly precisely and efficiently. The embossing means and/or the substrate particularly preferably comprise micro-or nanostructures, so that advantageously particularly small structures can be produced or embossed.

In a preferred embodiment of the device for the processing of substrates, provision is made such that the device is a film stamp mounting arrangement, and wherein the embossing means comprise a film stamp. The film stamp mounting arrangement is particularly well suited for use as an arrangement in the device, since an accommodated film stamp can carry out the structuring of the substrate particularly precisely in the evacuated processing or embossing space.

In a preferred embodiment of the device for the processing of substrates, provision is made such that the film stamp mounting arrangement comprises a frame fixable to the film mounting arrangement for accommodating the film stamp. The frame accommodates the film stamp and is preferably fixed by fixing means of the film mounting arrangement to the latter. An advantageous indirect and flexible arrangement of the film stamp on the film mounting arrangement can thus be predefined. In this way, a particularly good processing or embossing result can be achieved. In addition, with a released substrate, the latter can abut against the film stamp particularly well in a position for the embossing. The substrate is preferably held by capillary forces on the film stamp fastened in the frame.

In a preferred embodiment of the device for the processing of substrates, provision is made such that the film stamp can at least be partially released into the processing space by means of the flushing means. In other words, at least one flushing means is present on the rear side of the film stamp in the region of the holding surface of the film mounting arrangement, which flushing means enables partial flooding of the processing space during processing or embossing. The film stamp held fast in the frame is thus advantageously at least partially releasable. The film stamp can thus be raised by targeted flooding on the rear side of the film stamp and thus be released, so that a particularly good abutment or relaxation on the substrate can take place in the processing space. The processing space in the region of the rear side of the film stamp is separated fluidically, in particular by the film stamp itself, from the remaining region of the processing space. The frame particularly preferably remains fixed during the flushing with the flushing means, so that the position of the film stamp with respect to the substrate can advantageously be predetermined.

In a preferred embodiment of the device for the processing of substrates, provision is made such that the processing space is constituted at least partially by the frame. In other words, the frame represents a boundary of the processing space. Particularly preferably, the sealing means are at least partially constituted by the frame. In this way, the local and fluidically tight processing space can be provided particularly easily.

In a preferred embodiment of the device for the processing of substrates, provision is made such that the sealing means are arranged on the substrate mounting arrangement and/or the film mounting arrangement, in such a way that the frame can be arranged completely inside the processing space. In other words, the sealing means are arranged outside the mounting arrangements, in particular in the region of the periphery of the mounting arrangements. A particularly advantageous arrangement of the frame and the film stamp can thus take place completely in the processing space.

A particularly important aspect is that, by means of the method and the device for the processing, nano-embossing with a very precise overlay alignment is enabled. It is advantageously possible to control the contact between the substrate and the stamp in the best possible way. The filling behaviour of nanostructures, in particular with a small residual layer, is best carried out with flexible stamps which can relax on the substrate. In particular, controlled contacting or embossing is possible despite the soft and flexible embossing means.

With this idea in mind, the stamp is first fixed and aligned, then a vacuum is introduced between the substrate and the stamp in order to prevent air inclusions, and then the contact is produced by controlled bending of the substrate and/or of the stamp and/or initiation of an embossing wave. The process or the method enables efficient nano-embossing in a vacuum with precise control of the surface contacting for flexible stamps.

In addition, a particularly precise control in the contacting of the stamp and the substrate is possible, wherein the rigidity of the substrate at the same time permits a high-precision alignment the one with the other.

Amongst other things, it is also advantageous with the method and the device that a flexible stamp does not have to be dispensed with.

Furthermore, the entire mounting arrangements do not have to be loaded and adjusted in the vacuum.

Despite a vacuum, quicker contacting than with SmartNIL (WO2014/037044A1) and thus a higher throughput is possible.

A particularly important aspect is the embossing in a vacuum with a flexible film stamp, wherein the alignment of the stamp and the substrate takes place at normal pressure and wherein a local evacuable embossing space arises between the upper and the lower mounting arrangement with a sufficient approach of the mounting arrangements, which enables simplified contacting and embossing in a vacuum, wherein the contact between the substrate and the stamp film is produced by controlled bending of the substrate and/or of the film stamp and initiation of an embossing wave. Nano-embossing with a very precise overlay alignment and without air inclusions is thus possible with film stamps.

In the following text, the word stamp, film stamp, embossing stamp and nanostructured stamp are used synonymously. In addition, structuring and embossing are understood in the following to mean the production of micro-and/or nanostructures.

A further important aspect is the contacting, wherein only a partial area is contacted first by prestressing of the substrate and/or of the film stamp and then automatic contacting of the contact surfaces is brought about, wherein the entire substrate surface is preferably embossed without repetition of the aforementioned steps in an embossing space locally bounded by seals in a vacuum with a thin, flexible film stamp.

A further important aspect is that the alignment of the substrate and the film stamp first takes place under normal pressure. After a sufficient approach of the upper and the lower mounting arrangements and by contacting via the seals, a locally bounded embossing space only then arises, which is actively evacuated. The substrate and the film stamp are first fixed and aligned, then in the embossing space a vacuum is introduced between the substrate and the film stamp in order to prevent air inclusions and then the contact between the substrate to be embossed and the film stamp is produced via controlled bending of the substrate and initiation of an embossing wave.

The embossing front is started in the centre in particular with an actuator. By means of the propagation of the embossing front, the structured stamp surface in curable material, in particular resist lacquer, is imprinted on the substrate and the structures of the film stamp are replicated. The process can preferably be used for embossing a first layer or a second layer in combination with a precise adjustment (SmartView alignment).

The lacquering of the stamp and/or the substrate can optionally be separated from the embossing process in a dedicated module.

An essential advantage is that the alignment takes place at ambient pressure and thereafter the completely lacquered substrates can be contacted and embossed defect-free in a vacuum. The positioning errors do not occur which arise due to the movement of the substrates, which can in particular occur in an evacuable environment. Due to the locally bounded embossing space, a relatively rapid evacuation is possible compared to systems in which the entire embossing module has to be evacuated.

Film frames or also other stamp holders with frames are used for embossing with flexible stamps in a vacuum. The frame can also be used to define the vacuum zone or the evacuable embossing space. In a preferred embodiment, only a (rough) vacuum is adjusted between the film stamp and the substrate in the embossing space, so that the whole embossing module does not have to be evacuated.

Before the embossing, the substrate and the stamp are aligned with one another as precisely as possible. The alignment usually takes place by means of alignment marks.

The basic system can be provided in particular by an EVG SmartView system, wherein it is not necessary to see between the substrate and the film stamp, because the film stamp is preferably predominantly transparent. An alignment is thus advantageously not prevented by the film stamp, since the alignment optics can see through the film stamp.

The embossing device consists in particular of a stamp mounting arrangement and an arrangement for mounting a nanostructured stamp. The nanostructured stamp, in particular a film stamp, is preferably stretched in a film frame.

According to an advantageous embodiment, a detection device provides for the exact alignment of the substrate and the film stamp, whereby it detects the relative positions, relays them to the control unit, which then brings about an alignment of the substrate and the film stamp with one another.

The system preferably comprises a system for a contactless wedge error compensation between the film stamp and the substrate aligned in parallel, as described in detail and referred to in WO2012/028166A1.

A great challenge with embossing consists in the embossing process itself, i.e. during the initiation of the embossing wave after the punctiform, central contacting up to the complete contacting of the contact surfaces of the substrate and the film stamp. The alignment with respect to one another compared to the previous alignment can thereby still change decisively. For nano-embossing with a very precise overlay alignment, the contact between the substrate and the film stamp has to be controlled in the best possible way. The placing/contacting of the substrate and the film stamp is particularly critical, since errors can occur here, wherein the errors may be cumulative.

In the critical step of the contacting of the aligned contact surfaces of the substrate and the film stamp, an ever more exact adjustment accuracy or offset is desired. The alignment error amounts to less than 100 μm, in particular less than 10 μm, preferably less than 1 μm, with the greatest preference less than 100 nm, most preferably less than 10 nm.

The contacting of the contact surfaces and embossing of the corresponding surfaces by means of the devices takes place in particular at an embossing initiation point. The nano-imprint embossing of the substrate with the film stamp takes place along an embossing front running from the embossing initiation point to the side edges of the film stamp by release of the substrate and/or of the film stamp from the mounting surface.

The speed of the embossing wave can also be controlled by controlled release of the substrate and/or the film stamp. The fixing elements are preferably split up into separately controllable zones. A vacuum fixing is preferably used.

A pin in the central hole or a line, from which an overpressure can be generated by an introduced gas between the substrate mounting arrangement and the substrate, serve for the controllable sag of the fixed substrate (curvature means and/or curvature changing means). Further deformation means such as the application of a fluid are conceivable.

In a further embodiment, a pin in the central hole or a line, from which an overpressure can be generated by an introduced gas between the film stamp mounting arrangement and the film stamp, serve for the controllable sag of the fixed film stamp (curvature means and/or curvature changing means).

Prestressing and contacting at the embossing initiation point are described and referred to in detail in WO2015/161868A1. The precise description thereof will thus not be entered into here.

In a first embodiment, the substrate is fixed on the upper mounting arrangement and after the contacting, on the one hand is pulled downwards in a controlled manner by the force of gravity and on the other hand due to a force acting along the embossing wave and between the substrate and the stamp. The formation of a radially symmetrical embossing wave thus arises, which runs in particular from the centre to the side edge. The formation of the embossing wave is not limited to a radially symmetrical embossing wave. In an alternative embodiment, the formation of a linear embossing wave is desired. The contacting takes place at the edge of the substrate for this, and the linear embossing front propagates away from the edge point.

In a second, preferred embodiment, the substrate is fixed on the lower mounting arrangement. Only the fixing means in the edge region of the substrate mounting arrangement are used in the prestressing and contacting at the embossing initiation point. As soon as the substrate is in contact with the film stamp, the fixing is released from the substrate coated with the embossing compound by the interruption of the vacuum. As a result of the reduction of the under-pressure at the mounting surface, the release of the substrate can be carried out in a controlled manner. The fixing elements are controlled correspondingly. The film stamp remains unchanged fixed to the stamp mounting arrangement.

In a third, preferred embodiment, the substrate is fixed to the lower mounting arrangement, and the film stamp fixed to the upper mounting arrangement is bent by deformation means for the contacting of the substrate and the film stamp. The distance between the substrate and the film stamp is first reduced to a precisely defined distance, before the embossing process is started. The substrate and the film stamp are not placed flat on one another in the embossing process but are first brought into contact with one another at a point, e.g. the centre M of the substrate or an edge point R of the substrate, whereby the film stamp is pushed gently by deformation means against the substrate and thereby deformed. After the release of the deformed, i.e. bent film stamp (in the direction of the substrate lying opposite), a continuous and uniform embossing takes place along the embossing front due to the propagation of a radially symmetrical or linear embossing wave.

A further independent feature of the proposed invention is that, after the complete contact between the film stamp and the substrate, the flexible film stamp is “released” by means of flushing valves by a slight rear-side overpressure, whereas the film frame remains fixed. The film stamp can thus relax on the substrate. As a result of the capillary forces, the structures are filled and the film stamp can adapt conforming to the substrate surface due to the flexibility provided at this point in time. A high-resolution surface structuring can thus be carried out. The flushing or the pressure increase in the region of the rear side of the film stamp (flushing zone)-with a constant pressure or vacuum in the processing space-is used for the relaxation of the film stamp on the substrate, but also at the same time for a uniform application of force during embossing. In the embossing process, the filling of the structures of the film stamp by capillary forces is also assisted with the (slight) rear-side overpressure. The embossing time is thus advantageously shortened.

In order to keep the alignment accuracy as high as possible, provision is made in a first embodiment such that the imprint is externally cured and demoulded. After the embossing process in the alignment and embossing module, the stack is thus transferred to an unload station and then, in a curing and release module, the lacquer is crosslinked through the transparent film stamp by means of electromagnetic radiation, in particular UV light. In a second embodiment, the curing and the demoulding also takes place in the embossing module. Thus, only one module is necessary for the alignment, embossing, curing and demoulding, because of which the processing time can be optimised.

The UV light used is optionally broadband light or specially adapted to the photo-initiator used in the embossing lacquer. The wavelength range of the curable material lies in particular between 50 nm and 1000 nm, preferably between 150 mm and 500 nm, with greater preference between 200 mm and 450 nm.

In an alternative embodiment, the embossing compound can also be thermally cured. Thermal curing takes place between 0° C. and 500° C., preferably between 50° C. and 450° C., still more preferably 100° C. and 400° C., most preferably between 150° C. and 350° C., with utmost preference between 200° C. and 300° C.

At the end of the process, the film stamp is withdrawn in particular from the substrate and the substrate is unloaded. The system preferably comprises sensors for force monitoring for a control of the demoulding step.

In an exemplary embodiment of the method for the processing or the embossing of a substrate with a flexible film stamp, a general embodiment comprises in particular the following steps, preferably in the following sequence:
a) substrate coating or lacquering by means of an application device, e.g. a spin coating system,
b) adjustment of the substrate and the film stamp by means of an alignment device at normal pressure,
c) approach of the upper and/or the lower mounting arrangement until the formation of the evacuable embossing space by sealing,
d) evacuation/formation of the vacuum in the defined embossing space between the film stamp and the substrate,
e) embossing the substrate in a vacuum with the start of the imprint process by an actuator on the substrate and/or on the film stamp and embossing wave,
f) release of the substrate fixing,
g) gas flushing behind the film stamp for film relaxation and control of the embossing process,
h) UV irradiation of the curable material and
i) demoulding of the film stamp and substrate, in particular by evacuation of the flushing space by means of the flushing means.

If the device for the processing of substrates is disclosed in connection with means for the bonding, point a) more generally includes possible preliminary processes such as for example cleaning, surface activation, imprinting etc.

The device for the processing is preferably disclosed in connection with the production or embossing of micro-and/or nanostructures. A substrate can in particular be fixed with an embossing compound on a substrate mounting arrangement and a structured stamp can be contacted with the embossing compound. The fixing of the substrate can at least partially be removed and the embossing compound can be cured, wherein the embossing compound is demoulded from the structured stamp.

The stamp is particularly preferably an imprint stamp for use in imprint technology. The stamp is preferably constituted as a soft stamp for the imprinting of substrates. The stamp is preferably constituted with a backplate (backplane) in series, wherein the stamp and the backplate can generally consist of different materials. The use of a plurality of different materials leads to the stamps produced individually or combined therefrom being referred to as hybrid stamps. The backplate can serve as a stiffening of the stamp, but backplates are preferable which are very flexible and serve only as a carrier for the stamp.

The backplate can for example be a foil or made of glass. The backplate preferably includes a foil. The backplate then has in particular a thickness which is less than 1000 μm, preferably less than 500 μm, more preferably less than 250 μm, most preferably less than 100 μm.

In another embodiment, provision is made such that the backplate is a very thin and flexible glass plate. The glass plate is in particular thinner than 10 mm, preferably thinner than 5 mm, still more preferably thinner than 1 mm, most preferably thinner than 500 μm, with utmost preference thinner than 100 μm, most preferably of all thinner than 10 μm.

In particular, technical glasses are preferred with an adapted coefficient thermal expansion (CTE coefficient of thermal expansion).

Film stamps are a special kind of soft stamp, which consists of a thin film, onto which micro-and/or nano-embossing structures are applied. The film and the embossing structures form the soft stamp. Hard stamps are used as master stamps for producing the soft stamps as a negative of the hard stamp. The embossing compound for the stamp production is present on the foil which serves as a backplate. After the release of the master stamp from the cured embossing compound, the produced stamp preferably remains on the backplate, in particular on the foil.

The soft stamp includes in particular one of the following materials:
thermoplastic,
elastomer and/or
duroplast.

The film stamp includes in particular at least one of the following materials:
poly(organo)siloxane (silicone), in particular
   polyhedral oligomeric silsesquioxane (POSS) and/or
   polydimethane siloxane (PDMS),
perfloropolyether (PFPE) and/or
tetraethylorthosilicate (TEOS).

For the embossing with flexible stamps in a vacuum, film frames or also other stamp holders with frames are preferably used. The nanostructured stamp, in particular a film stamp, is stretched in the frame.

The frame on the film stamp enables a rapid and simple replacement of stamps, the process in particular being simplified by the possible automation in the replacement of the film stamp. So-called film frames are preferred as frames, which are industrially normalised and standardised.

The film stamp with a frame is preferably larger than the substrate. The frame is used to define the local vacuum zone or the evacuable embossing space. With sufficient approach of the upper and the lower mounting arrangements, a ring seal of the substrate mounting arrangement makes contact with the frame in a first embodiment, so that an evacuable embossing space arises between the film stamp with the frame and the substrate. In a further embodiment, the contact point is located directly after the frame.

The film stamp is predominantly UV transparent. The wavelength range for the optical transparency lies in particular between 100 nm and 1000 nm, preferably between 150 nm and 500 nm, more preferably between 200 nm and 450 nm, most preferably between 250 nm and 450 nm. The film stamp can also be transparent for other regions of electromagnetic radiation. The film stamp can in particular also be transparent in the infrared region.

In an independent embodiment, the embossing compound is thermally cured. In this embodiment, the film stamp does not have to be transparent for electromagnetic radiation and consists in particular of a metallic foil. The in particular flexible film stamp includes in particular at least one of the following materials:
plastic
metal
metal alloy.

The substrates can have any arbitrary shape, but are preferably round. The diameter of the substrates is in particular industrially standardised. For wafers, the diameters common in the industry are 1 inch, 2 inches, 3 inches, 4 inches, 5 inches, 6 inches, 8 inches, 12 inches and 18 inches. However, this embodiment can in principle handle any substrate, irrespective of its diameter.

In the alignment of the film stamp and the substrate, the latter are aligned relative to one another, in particular with optical aids. The alignment takes place in particular with alignment marks, which are located on the film stamp and on the substrate, wherein the substrate and the film stamp have at least two alignment marks. A very precise positioning of the film stamp relative to the substrate is thus achieved. The film stamp and/or the substrate are transparent for the electromagnetic radiation used for the alignment. In particular, the film stamp is transparent for the electromagnetic radiation used for the alignment.

The substrate and the film stamp frame and stamp backplate are fixed by at least one fixing element and the corresponding mounting arrangement. The fixing elements can be switched on and off. The fixing elements are preferably vacuum fixings, in particular with
individually controllable vacuum tracks and/or
in each case a plurality of vacuum tracks connected to one another (vacuum segments).
mechanical fixings, in particular clamps,
electrical fixings, in particular
   electrostatic fixings and/or
   magnetic fixings,
adhesive fixings.

The fixing elements for the substrate, the film stamp frame and the film stamp backplate are preferably vacuum fixings. The at least one fixing element is in particular electronically controllable.

The vacuum fixing preferably includes a plurality of vacuum tracks, which emerge at the holding surface of the mounting arrangement. The vacuum tracks are preferably individually controllable.

In a preferred embodiment, several vacuum tracks are united to form vacuum track segments, which can be individually controlled, and can therefore be evacuated or flooded. Each vacuum segment is however independent of the other vacuum segments. The possibility is thus provided of constructing individually controllable vacuum segments.

Such individually controllable vacuum tracks or vacuum segments are used in the holding surface of the film stamp mounting arrangement in order to define separated fixing elements or fixing zones in each case for the
film stamp frame,
outer region of the backplate without structuring and/or
stamp region of the backplate with structuring, for an improved control of the embossing process.

Vacuum segments for the substrate fixing on the substrate mounting arrangement are preferably designed circular. A targeted, radially symmetrical fixing, in particular leading from the inside outwards, and/or release of the substrate from the substrate mounting arrangement is enabled. Alternatively, a fixing and/or release of the substrate and/or the film stamp from the mounting arrangement carried out linearly is also possible.

In a first embodiment of the film stamp mounting arrangement and/or substrate mounting arrangement, a pin in the central hole or a line, from which an overpressure can be generated by an introduced gas between the holding surface of the substrate mounting device and the substrate, serve for the controllable sagging of the fixed film stamp and/or substrate. The film stamp or the substrate remains fixed in an annular manner in the edge region.

In a second embodiment of the film stamp and/or substrate mounting arrangement, an inner vacuum segment, which serves as a vacuum fixing, can be switched in such a way that via the latter a gas and/or a gas mixture can be pumped into the intermediate space between the holding surface of the mounting arrangement and the film stamp side or substrate rear side, for the controlled sagging of the film stamp and/or substrate fixed at the edge. The at least one fixing element can then be used at the same time, after switching over, as a curvature means. As a result of the design of the vacuum zones or of the vacuum segments, an active control of the pressure zones takes place as a curvature means for the embossing.

The selection of the introduced process gases as a gas and/or gas mixture can have an additional effect on the processing of substrates (embossing, imprinting, bonding). For example, a deionised gas can be used against static charging or slightly moistened helium (He) or nitrogen (N2) gas can be used for regulating the humidity.

An essential advantage of the device is that the alignment or adjustment of the substrate and the film stamp is carried out with a high degree of accuracy under normal pressure and then, by the formation of a local, spatially bounded embossing space, defect-free and simplified embossing is possible in a vacuum.

The film stamp frame can also be used to define the vacuum zone or the evacuable embossing space.

A defined region or processing space is sealed off by means of seals, in particular ring seal(s) between the upper and the lower mounting arrangement.

The ring seal(s) are located in a preferred embodiment on the substrate mounting arrangement.

The evacuable embossing space arises through the approach of the upper and the lower mounting arrangement until the formation of the evacuable embossing space by sealing after contacting of the stamp mounting arrangement and the substrate mounting arrangement provided with ring seal(s). In a preferred embodiment, the seals are located after the film stamp frame, so that the entire film stamp frame is located in the embossing space.

Inlet openings for the active evacuation of the embossing space are located in the region of the embossing space, preferably in the substrate mounting arrangement. The inlet openings according to an embodiment of the invention are either affixed vacuum holes or comparable vacuum elements, with the aid of which the embossing space can be evacuated in a controlled manner.

In a preferred embodiment, only a rough vacuum is set between the film stamp and the substrate in the locally bounded embossing space.

A particular advantage of the embodiments and processes includes the fact that the entire device or the entire embossing module does not have to be evacuated. The evacuation of the embossing space is therefore only carried out when a vacuum is required. As a result of the smaller space which has to be evacuated, simplified embossing in a vacuum is possible.

In particular, the alignment and the adjustment of the substrate and the film stamp is first carried out at normal pressure. Then, for defect-free embossing, the embossing process is only carried out after evacuation of the embossing space.

After the embossing process, the substrate and the film stamp are preferably completely contacted. After the full-area contact between the film stamp and the substrate, the flexible film stamp can be lifted by a slight overpressure by means of flushing valves. The flushing valves are preferably located in the outer region of the backplate or the film. This outer region has no structuring and is not part of the stamp surface. In the meantime, the film stamp frame remains fixed on the stamp mounting arrangement, so that the film stamp can relax on the substrate. The structures are filled by the capillary forces and the film stamp can be adapted to conform to the substrate surface by the flexibility provided at this time. A high-resolution surface structuring can thus be implemented.

The stamp mounting arrangement in particular comprises at least one flushing valve for the rear-side lifting of the film stamp from the holding surface of the mounting arrangement. The at least one flushing valve is preferably a fluid element, via which a gas and/or a gas mixture can flow out in order to produce an overpressure between the holding surface of the stamp mounting arrangement and the film stamp. The flushing valves are preferably located in the outer region of the backplate or the film. This outer region has no structuring and is not part of the stamp surface.

In a first embodiment, the vacuum fixing for the film stamp frame and for the regions of the backplate with and without structuring is separated from the fluid elements for an overpressure for lifting the film stamp (lifting element).

In a second embodiment, individual fixing elements, in particular vacuum fixings for the outer region of the backplate, which are not structured, can be switched over and be supplied with overpressure. Individual fixing elements can if need thus be used at the same time as the lifting element and thus relax the film.

In a preferred embodiment of the method for the alignment and embossing, provision is made such that the flushing or pressure increase in the region of the rear side of the film stamp (flushing zone) is used for relaxing the film stamp on the substrates, but at the same time also for a uniform application of force during embossing. In the embossing process, the filling of the structures of the film stamp by capillary forces is additionally assisted with the (slight) rear-side overpressure.

In a preferred embodiment of the method for the alignment and embossing, provision is made such that the pressure difference between the processing space and the region of the rear side of the film stamp (flushing zone) is also used for the demoulding of the film stamp from the embossing compound.

In a preferred embodiment of the method for the alignment and embossing, provision is made such that an active control of the pressure zones for the embossing and demoulding takes place by means of the pressure adjustment and pressure regulation respectively in the processing space and in the flushing zone. This pressure difference thus arising between the two pressure zones is used to generate external forces, which act on the film stamp, in the embossing and demoulding.

The dimensions of the individual nanostructures of the embossing pattern of the embossing means or of the film stamp preferably lie in the millimetre and/or in the nanometre range. The dimensions of the individual nanostructures of the embossing means, in particular of the flexible film stamp, are less than 1000 μm, preferably less than 10 μm, more preferably less than 100 nm, most preferably less than 10 nm.

The precision with which the detection devices, in particular alignment optics, can be moved individually is better than 1 mm, preferably better than 100 μm, more preferably better than 10 μm, more preferably better than 1 μm, with still more preference better than 100 nm, with greatest preference better than 10 nm, with utmost preference better than 1 nm.

In a preferred embodiment, only a rough vacuum is set between the film stamp and the substrate in the locally bounded embossing space (processing space) after the alignment is completed.

In the evacuation, the pressure in the embossing space is less than 500 mbar, preferably less than 300 mbar, most preferably less than 250 mbar. In particular, the rough vacuum is preferably set between 300 mbar and 1 mbar, most preferably between 250 mbar and 100 mbar.

The pressure in the region of the rear side of the film stamp (flushing zone) is preferably set between 1 mbar and 1500 mbar. In a preferred embodiment, in addition to the rough vacuum in the processing space, the pressure in the region of the rear side of the film stamp (flushing zone) is preferably set between 1100 mbar and 1250 mbar during and/or after the (complete) contacting between the film stamp and the substrate coated with the embossing compound.

The pressure difference between the processing space and the region of the rear side of the film stamp (flushing zone) is also used for the demoulding of the film stamp from the embossing compound. For example, the pressure in the processing space is set to normal pressure for this, whereas the pressure in the region of the rear side of the film stamp (flushing zone) is set between 1100 mbar and 1500 mbar.

In a preferred embodiment of the device for the processing of substrates, provision is made such that the pressure difference between the processing space and the rear side of the film stamp is used for the active control of the embossing and the demoulding. As a result, external forces are produced, which are used for the processing of the substrate. The range of the produced forces preferably lies between 100 N and 10 kN.

The UV light used is optionally broadband light or specially adapted to the photo-initiator used in the embossing lacquer. The wavelength range of the curable material lies in particular between 50 nm and 1000 nm, preferably between 150 nm and 500 mm, more preferably between 200 nm and 450 nm.

### BRIEF DESCRIPTION OF THE DRAWINGS

Further advantages, features and details of the invention emerge from the following description of preferred examples of embodiment and with the aid of the drawings. The latter show, diagrammatically:

FIG. 1a: a cross-sectional view of the device of a first embodiment in a first process step,

FIG. 1b: a cross-sectional view of the device of a first embodiment in a second process step,

FIG. 1c: a cross-sectional view of the device of a first embodiment in a third process step,

FIG. 1d: a cross-sectional view of the device of a first embodiment in a fourth process step,

FIG. 1e: a cross-sectional view of the device of a first embodiment in a fifth process step,

FIG. 2a: a cross-sectional view of the device of a second embodiment in a first process step,

FIG. 2b: a cross-sectional view of the device of a second embodiment in a second process step,

FIG. 2c: a cross-sectional view of the device of a second embodiment in a third process step,

FIG. 2d: a cross-sectional view of the device of a second embodiment in a fourth process step,

FIG. 2e: a cross-sectional view of the device of a second embodiment in a fifth process step,

FIG. 2f: a cross-sectional view of the device of a second embodiment in a sixth process step,

FIG. 2g: a cross-sectional view of the device of a second embodiment with a substrate stamp stack in the exposure and demoulding module in a first process step,

FIG. 2h: a cross-sectional view of the device of a second embodiment in a with a substrate stamp stack in the exposure and demoulding module in a second process step,

FIG. 2i: a cross-sectional view of the device of a second embodiment with a substrate stamp stack in the exposure and demoulding module in a third step,

FIG. 2j: a cross-sectional view of the device of a second embodiment with a substrate stamp stack in the exposure and demoulding module in a fourth process step,

FIG. 3a: a cross-sectional view of the device of a third embodiment with a loaded substrate and film stamp with a film frame in a first process step,

FIG. 3b: a cross-sectional view of the device of a third embodiment in a second process step, and

FIG. 3c: a cross-sectional view of the device of a third embodiment in a third process step.

The same components or components with the same function are denoted by the same reference numbers in the figures. Size relationships may be incorrectly represented for the sake of clarity.

### DETAILED DESCRIPTION OF THE INVENTION

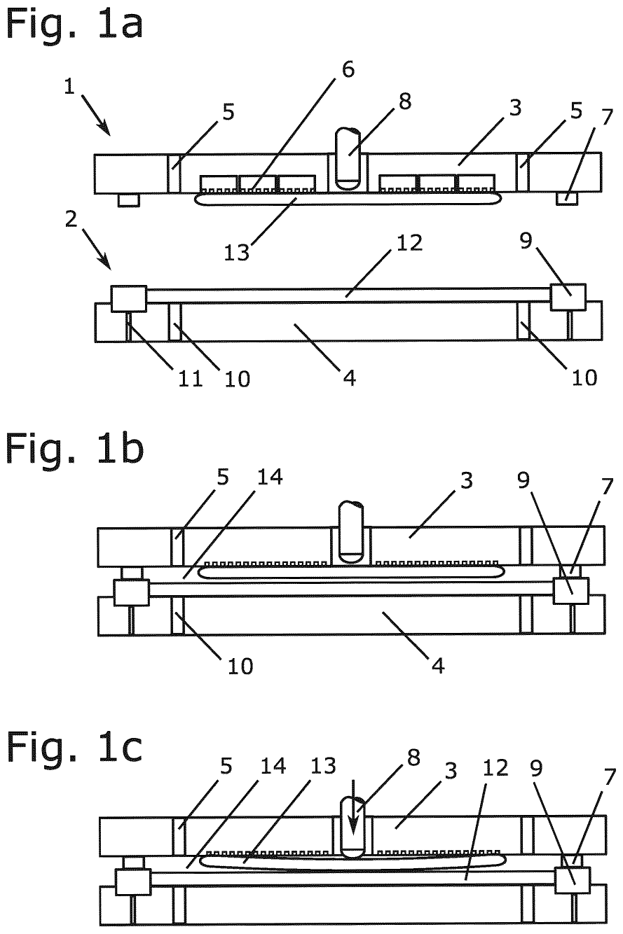

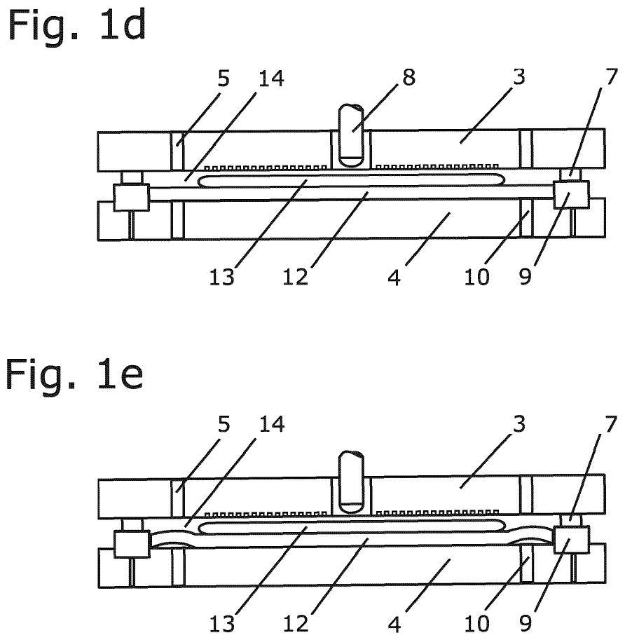

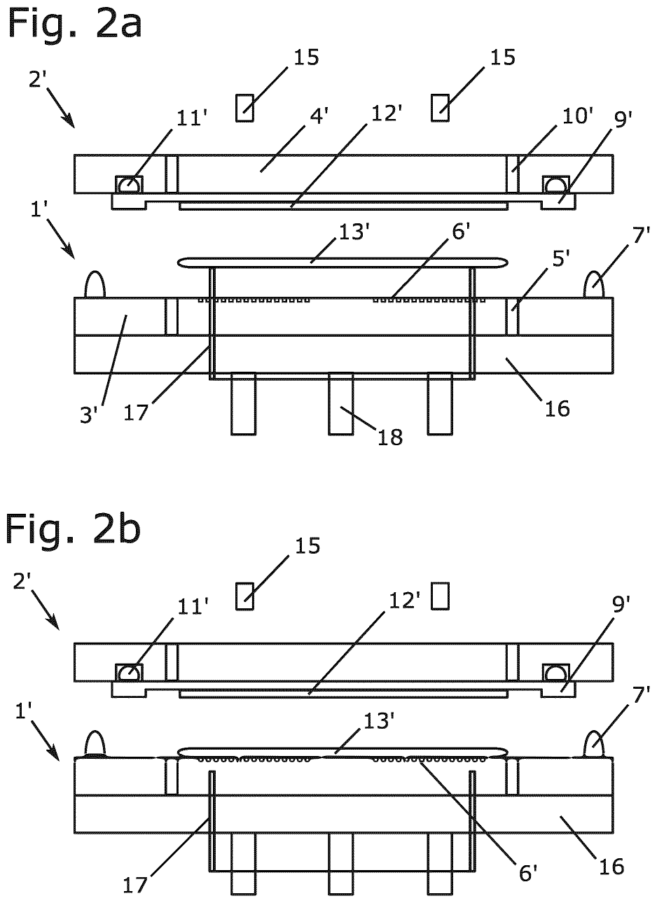

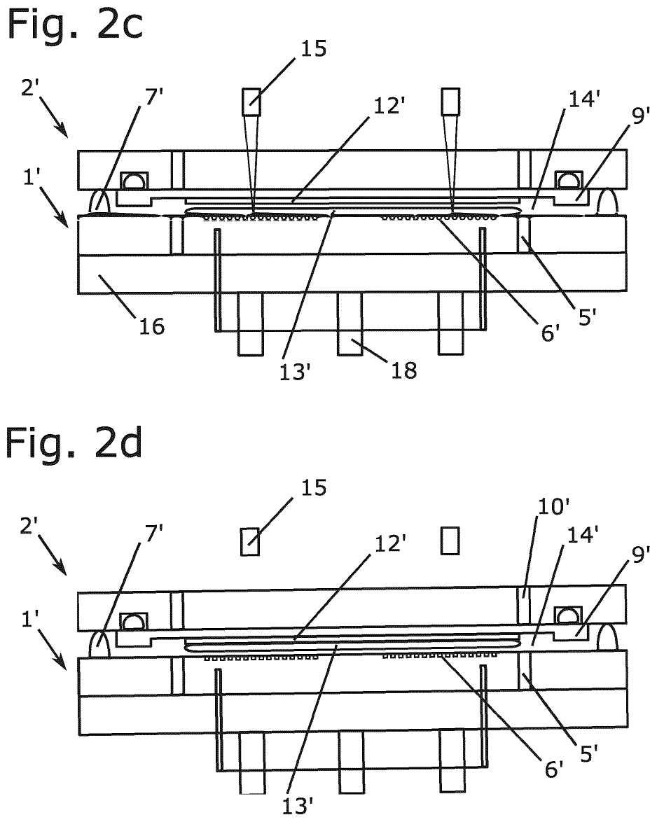

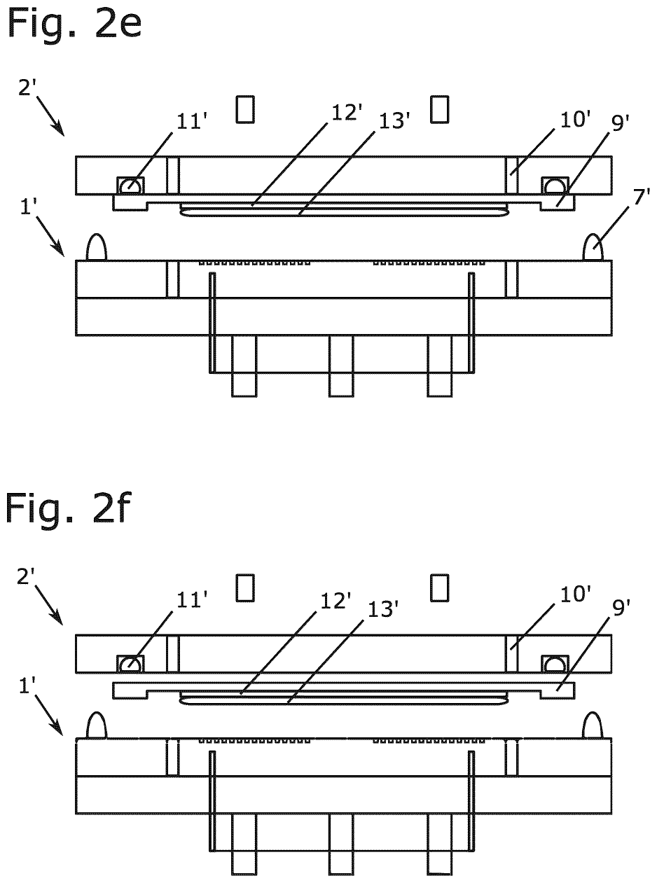

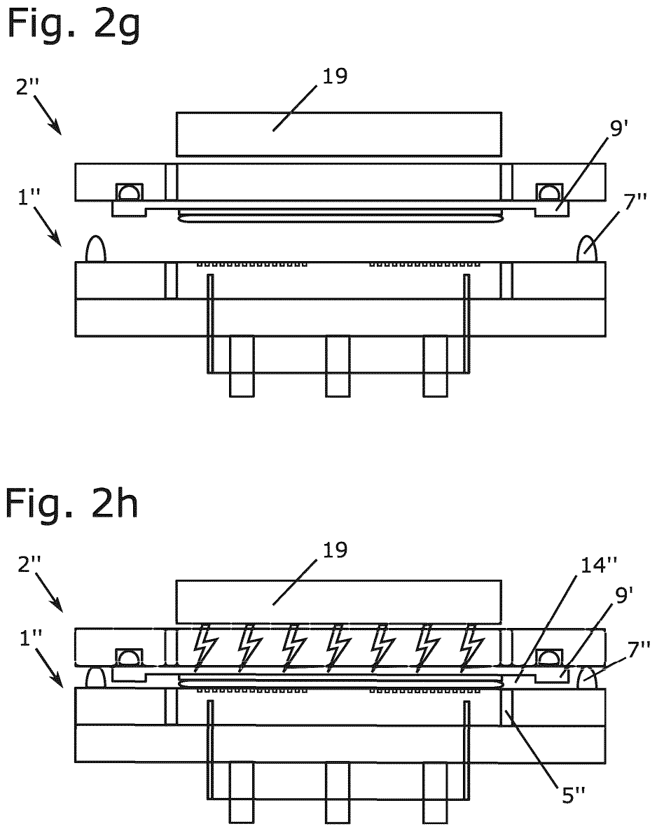

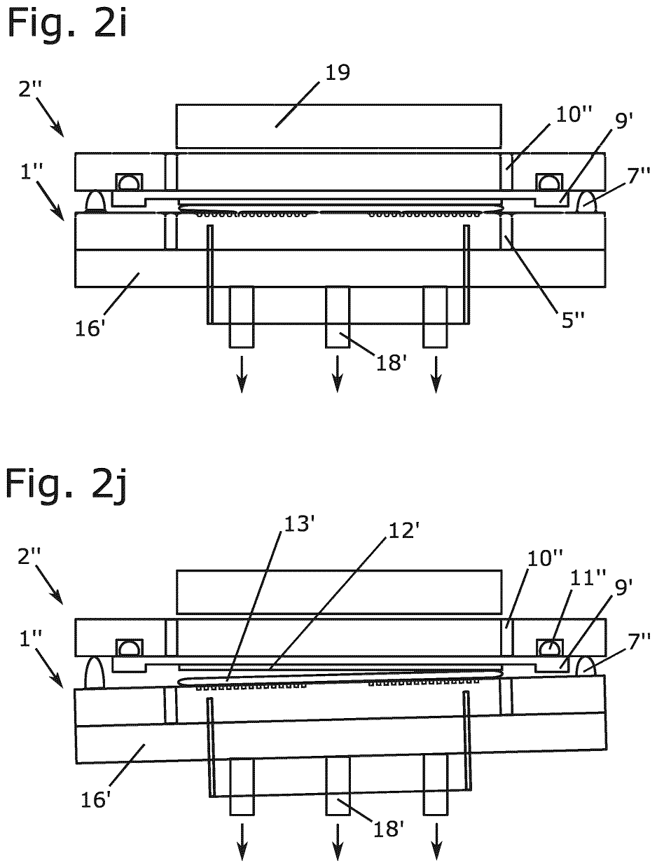

FIGS. 1a to 1e represent the method for the processing as an embossing process in the alignment and embossing module in a first embodiment analogous to fusion bonding with the film stamp below and the substrate above. The arrangement is also possibly conceivable inverted, conventionally with the film stamp above and the substrate below, as is represented in a second embodiment of FIGS. 2a to 2j. The device for the processing is represented in the figures for example by an embossing device. The device for the processing can for example also be a laser processing device, a lacquering device, a bonding or debonding device. The local processing space can then be correspondingly formed around the substrate accordingly between the devices or the elements of the devices and the substrate mounting arrangement.

An essential advantage of the device is that the adjustment and approach of the substrate and the device or the film stamp is first carried out with a high degree of adjustment accuracy under normal pressure and then defect-free and simplified embossing is possible in a vacuum in a spatially bounded, evacuable embossing space.

FIG. 1a shows the mounting arrangements 1 and 2 of a device for mounting substrate 13 and film stamp 12 with film frame 9. Substrate mounting arrangement 1 contains a central opening for the passage of an actuator 8 or actuator device (not represented). In this first exemplary embodiment, the embossing process (nanoimprint process) is initiated with actuator 8 in the centre of the substrate. Actuator 8 can have different shapes or embodiments. Instead of an actuator pin as actuator 8, application of pressure with a fluid or a gas is also possible as an alternative. This opening for actuator 8 according to FIG. 1a can have different sizes and shapes.

In FIG. 1a, film stamp 12 with film frame 9 has already been accommodated on film stamp mounting arrangement 2. The fixing of film frame 9 takes place by means of fixing elements 11 and via vacuum track segments distributed in the holding surface of mounting arrangement 2, which fix defined zones of the film rear side (not represented). FIG. 1a also shows substrate mounting arrangement 1 with a loaded substrate 13. Substrate 13 is fixed by a vacuum or under-pressure via vacuum tracks 6. In a preferred embodiment according to FIG. 1a, several vacuum tracks 6 are united to form vacuum track segments, which can be individually controlled, and can therefore be evacuated or flooded.

Substrate mounting arrangement 1 according to FIG. 1a contains seals, in particular sealing rings 7, in order to form a spatially bounded and sealed embossing space 14 after contacting with lower film stamp mounting arrangement 2. Since the stamp, in particular a film stamp 12 with frame 9, is usually larger than substrate 13, loading or lacquering of the stamp preferably takes place outside the substrate zone.

In the next process step according to FIG. 1b, embossing space 14 is formed after the alignment or adjustment and approach up to the contacting of upper and lower mounting arrangements 1, 2 at seals 7. Embossing space 14 is evacuated via vacuum lines 5 in substrate mounting arrangement 1. Frame 9 is used according to FIG. 1b in order to define local vacuum zone or evacuable embossing space 14. Sealing after frame 9 is also possible as an alternative.

In the next process step according to FIG. 1c, film stamp 12 and substrate 13 are contacted as punctiform as possible at a partial area after the completed evacuation of embossing space 14 and thus after introduction of the vacuum between substrate 13 and film stamp 12. The contacting shown in FIG. 1c takes place by a concentric deformation of substrate 13 by means of the pressure exerted by actuator 8, in particular in the centre of substrate 13. Substrate 13 remains fixed in an annular manner in the edge region. Substrate 13 is bent in a controlled manner until the contacting of film stamp 12 and then released and, after complete release, contacts film stamp 12 over the whole area. The vacuum prevents possible air inclusions.

Instead of a pin as actuator 8 in the central hole of the substrate mounting arrangement, a line from which an overpressure can be generated by an introduced gas between the holding surface of the substrate mounting arrangement and substrate 13 is also possible for the controllable sagging of fixed substrate 13.

The vacuum fixing for substrate 13 preferably consists of a plurality of vacuum tracks 6, which emerge at the holding surface of the substrate mounting arrangement. In a preferred embodiment, several vacuum tracks 6 are united to form vacuum segments, which can be controlled individually. The vacuum segments for the substrate fixing to the substrate mounting arrangement are preferably designed circular. A controlled, radially symmetrical release of the substrate 13 from the substrate mounting arrangement, running in particular from the inside outwards, can thus be enabled after the contacting.

FIG. 1d shows a completed embossing wave, in which the embossing front has reached the edge of substrate 13. Substrate 13 and film stamp 12 are almost completely contacted and substrate 13 is no longer fixed to the upper substrate mounting arrangement. Actuator 8 can if required firstly remain in contact with the substrate and/or be retracted into the central hole.

Film stamp mounting arrangement 2 according to FIGS. 1a to 1e comprises additional valves or gas lines, in particular via at least one flushing valve 10 for the rear side lifting of film stamp 12 from the holding surface of film stamp mounting arrangement 2. The at least one flushing valve 10 is preferably a fluid element, via which is a gas and/or gas mixture can flow out in order to generate an overpressure between the holding surface of the stamp mounting arrangement and film stamp 12. The flushing valves are preferably located in the outer region of the backplate or the film of film stamp 12. This outer region has no structuring and is not part of the stamp surface.

According to FIG. 1e, after the complete contact between film stamp 12 and substrate 13, flexible film stamp 12 is “released” by an overpressure between the outer holding surface of the film stamp mounting arrangement and film stamp 12. In the meantime, film stamp frame 9 remains fixed on the film stamp mounting arrangement, so that film stamp 12 can relax on the substrate. The structures are filled by the capillary forces and film stamp 12 can adapt to conform to the substrate surface by the flexibility provided at this time. The delta of the ambient pressure can be used as an additional external force for improving the filling behaviour.

In order to keep the alignment accuracy as high as possible, provision is made such that the imprint is cured and demoulded externally in a second module of the device. Alternatively, this would also be conceivable with this structure, but would make the structure much more complex, and cause an undesired temperature input.

FIGS. 2a to 2j show the process steps in the second embodiment of the device and the method.

The device comprises in particular a module group with a common working space, which if required can be closed off with respect to the ambient atmosphere. The device consists in particular of a least two modules. Alignment and embossing are carried out in a first module according to FIGS. 2a to 2f. Curing and demoulding are carried out in particular in a second module according to FIGS. 2g to 2j. The lacquering can be carried out separate from the embossing process in an independent module.

In a first process step, substrate 13′ and film stamp 12′ are loaded and accommodated and fixed on respective mounting arrangements 1′, 2′.

FIG. 2a shows mounting arrangements 1′ and 2′ of a device for the mounting of substrate 13′ and film stamp 12′ with film backplate and frame 9′. In this second embodiment, film stamp 12′ is located above on film stamp mounting arrangement 2′ and substrate 13′ below on substrate mounting arrangement 1′

In FIG. 2a, film stamp 12′ with backplate together with film frame 9′ has already been accommodated on the film stamp mounting arrangement 2′. The fixing of film frame 9′ takes place by means of fixing elements 11′ and also via vacuum track segments distributed in the holding surface of mounting arrangement 2′, which fix defined zones of the film rear side (not represented). In particular, structured stamp regions and non-structured regions of the (film) backplate are separated into different vacuum track segments.

In FIG. 2a, substrate 13′ has been placed on loading pins 17 of substrate mounting arrangement 1′.

FIG. 2b shows a substrate 13′ after the mounting on the mounting surface of mounting body 3′ of a substrate mounting arrangement 1′, wherein the loading takes place from above. Substrate 13′ is fixed by vacuum or under-pressure via vacuum tracks 6′. In a preferred embodiment, several vacuum tracks 6′ are united to form vacuum track segments, which can be controlled individually, and can therefore be evacuated or flooded (not represented).

When substrate 13′ is located on the lower mounting arrangement as represented in the embodiment according to FIGS. 2a to 2j, a mechanical fixing for substrate 13′ is possible as an alternative or in addition to vacuum fixing in a further embodiment.

The coating or lacquering of substrate 13′ with the embossing compound (embossing lacquer) can optionally be carried out separate from the embossing process in an independent module or can be carried out in the alignment and embossing module after fixing of substrate 13′. The invention can be used in combination with established industrial lacquering processes such as for example spin coating methods. The lacquering of the substrate is thus quick, defect-free, complete, free from particles and standardised, which also brings throughput advantages in the embossing step. In a first embodiment, substrate 13′ is coated before loading with an embossing compound. In a further embodiment, substrate 13′ is only coated after the loading and fixing with an application device (not represented).

In a second process step according to FIG. 2c, film stamp 12′ is aligned relative to substrate 13′, in particular with optical aids 15. Film stamp 12′ and substrate 13′ are approached relatively towards one another.

In a preferred embodiment, provision is made such that substrate 13′ and/or substrate mounting arrangement 1′ can be moved in at least three degrees of freedom, preferably in at least four degrees of freedom, more preferably in at least five degrees of freedom, most preferably in all six degrees of freedom.

In the alignment and embossing module according to FIGS. 2a to 2f, there are located, in particular at the upper and lower side, in each case an adjustment unit 16 for substrate 13′ and film stamp 12′. Corresponding mounting arrangements 1′, 2′ are located on each adjustment unit. Each mounting arrangement 1′, 2′ has in particular six degrees of freedom, three degrees of freedom in the translation along the X-, Y-and Z-direction and three degrees of freedom in the rotation about the X-, Y-and Z-axis. The translation degrees of freedom serve for the displacement of mounting arrangement 1′, 2′ and thus of substrate 13′ or film stamp 12′ within the X-Y plane spanned by the X and Y-direction and the approach of substrate 13′ and film stamp 12′ towards one another along the Z-direction. The possibility of rotation about the X-, Y-and Z-axis serves to carry out a wedge error compensation (WEC Z-axis 18) and/or the orientation of the substrate and/or the film stamp. The rotations about the X-, Y-and Z-axis are in particular rotations with small angles of rotation, so that one could also speak of tilting.

The Z-direction or Z-axis runs in the loading position perpendicular as a surface normal to the holding surface of mounting arrangements 1, 1′, 1″, 2, 2′, 2″. The X-and Y-directions or X-and Y-axes run perpendicular to one another and parallel to or in the holding surface of the mounting arrangements.

In another embodiment, provision is made such that the positioning, holding and movement system of upper and lower mounting arrangements 1, 1′, 1″, 2, 2′, 2″ is constituted for at least one degree of freedom with a rough drive and a fine drive.

In a preferred embodiment, provision is made such that mounting arrangements 1, 1′, 1″, 2, 2′, 2″ comprise a central control unit and/or regulating unit for the control and/or regulation of movements and/or sequences, in particular of the fixing of substrate 13, 13′ and film stamp 12, 12′ and the position of mounting arrangements 1, 1′, 1″, 2, 2′, 2″. In addition, mounting arrangements 1, 1′, 1″, 2, 2′, 2″ comprises at least one sensor (not represented) for measuring influencing factors, in particular at least one distance and/or position sensor.

In a third process step according to FIG. 2c, after sufficient approach of mounting arrangements 1′, 2′, the formation of a locally bounded and evacuable embossing space 14′ takes place. A defined region 14′ is sealed by means of seals 7′, in particular ring seal(s) between upper and lower mounting arrangements 1′, 2′. This region can be evacuated if required. Ring seal(s) 7′ are located on substrate mounting arrangement 1′ in a preferred embodiment. This evacuable embossing space 14′ arises through the approach of the upper and the lower mounting arrangement until the formation of the embossing space by sealing after contacting of stamp mounting arrangement 2′ and substrate mounting arrangement 1′ provided with ring seal(s) 7′. In a preferred embodiment, the seals are located after film stamp frame 9′, so that the entire film stamp frame 9′ is located in the embossing space. In alternative embodiments, seals 7′ can be affixed in each case on both mounting arrangements or only one of mounting arrangements 1′, 2′.

In the region of embossing space 14′, there are located, preferably in substrate mounting arrangement 1′, vacuum inlet openings 5′ for the active evacuation of embossing space 14′. Inlet openings 5′, according to a preferred embodiment of the invention, are either affixed vacuum holes or comparable vacuum elements, with the aid of which embossing space 14′ can be evacuated in a controlled manner.

FIG. 2c shows the constituted embossing space 14′ by contacting of upper and lower mounting arrangement 1′, 2′at sealing ring 7′ after the aligned joining. The distance between substrate 13′ and film stamp 12′ has been reduced to a precisely defined distance before the embossing process is started.

Film stamp 12′ is still aligned relative to substrate 13′, with optical aids 15, before the evacuation of embossing space 14′ is started. A further fine alignment of film stamp 12′ can also take place relative to substrate 13′ after the evacuation of embossing space 14′. Beforehand, the alignment takes place, in particular with optical aids 15, before the evacuation of the processing space, in order that a particularly precise alignment can advantageously take place at normal pressure. Furthermore, substrate 13′, after the evacuation of the processing space, can also for example be rotated, in order to compensate for a wedge error. This is carried out in particular by means of a WEC 18.

In fourth process step according to FIG. 2d, embossing of the embossing compound takes place with film stamp 12′. An actuator is used for this, in order to curve substrate 13′ in a convex manner, in particular concentrically, and thus to contact film stamp 12′ first with its central part (not represented). Substrate 13′ remains fixed during the deformation in particular at the peripheral edge with substrate mounting arrangement 1′.

In this second embodiment of substrate mounting arrangement 1′, an inner vacuum segment, which serves as a vacuum fixing, can be switched in such a way that a gas and/or a gas mixture can be pumped via the latter into the intermediate space between the holding surface of substrate mounting arrangement 1′ and the substrate rear side, for the controllable sagging of the substrate fixed at the edge. The at least one central fixing element can thus be used at the same time as curvature means after switching over.

After the release of deformed, i.e. sagging, substrate 13′, a continuous and uniform embossing along the embossing front takes place through the propagation of an embossing wave.

According to FIG. 2d, substrate 13′ and film stamp 12′ with the embossing compound lying in between are held together by capillary forces and contacted over the whole area. For this purpose, at least film stamp 12′ must have a high degree of flexibility. On account of the viscosity of the embossing compound, the intermediate spaces of film stamp 12′ are also in particular completely filled therewith by the capillary effect.

A further independent feature of the proposed invention is that, after the complete contact between film stamp 12′ and substrate 13′, flexible film stamp 12′ is relaxed by a slight rear-side overpressure by means of flushing valves 10′, whereas film frame 9′ remains fixed. Film stamp 12′ can thus relax on substrate 13′. As a result of the capillary forces, the structures are filled and, as a result of the flexibility provided at this time, film stamp 12′ can adapt to conform to the substrate surface. A high-resolution surface structuring can thus be carried out.

In a fifth process step, the curing of the embossing compound takes place. In order to keep the alignment accuracy as high as possible, provision is made such that the imprint is cured and demoulded externally. According to FIGS. 2e and 2f, after opening of the embossing space, frame 9′ with film stamp stack and substrate stack is removed from upper film stamp mounting arrangement 2′ and transferred into the curing and demoulding module.

According to FIGS. 2g and 2h, after the embossing process in the alignment and embossing module, the film stamp substrate stack is transferred onto an unload station (not represented) and then, in the curing and release module, the embossing compound or the lacquer is crosslinked through the transparent film stamp by means of UV light.

The curing and release module according to FIG. 2g comprises, similar to the alignment and embossing module according to FIGS. 2a to 2f, a substrate mounting arrangement 1″ and a film stamp mounting arrangement 2″, the precise description of which will not be entered into here.

After the fixing of the film stamp substrate stack on film stamp mounting arrangement 2″according to FIG. 2 g, mounting arrangements 1″, 2″ are approached up to a defined distance according to FIG. 2h for the formation of space 14″ defined by a ring seal(s) 7″. Space 14″ is evacuated if need be. UV lamp house 19 enables the irradiation of the embossing lacquer by means of UV light. In the curing with UV radiation, a temperature control takes place and if need be a temperature compensation.

In a sixth process step, demoulding of film stamp 12′ from the embossing compound takes place according to FIGS. 2i and 2j. At the end of the process, film stamp 12′ is withdrawn in particular from substrate 13′ in the curing and release module and substrate 13′ is unloaded. The system preferably comprises sensors for force monitoring for a control of the deformation step.

In the curing and release module according to FIGS. 2g to 2j, located in particular at the underside, there is an adjustment unit 16′ for mounting arrangement 1″. Mounting arrangement 1″ has in particular six degrees of freedom, three degrees of freedom in translation along the X-, Y-and Z-direction and three degrees of freedom in rotation about the X-, Y-and Z-axis. The degrees of freedom in translation serve for the displacement of mounting arrangement 1″ and thus substrate 13′ inside the X-Y plane spanned by the X-and Y-direction as well as the movement of substrate 13′ and film stamp 12′ towards one another along the Z-direction. The possibility of rotation about the X-, Y- and Z-axis serves to carry out wedge error compensation (WEC Z-axis 18′) and/or the orientation of substrate 13′ for the demoulding.

FIGS. 2h and 2i show lines 5″, which can be used optionally as vacuum lines for the evacuation of space 14″ or as flushing valves for flushing or the formation of an overpressure in space 14″ by means of gas or gas mixtures. The demoulding is assisted by flushing of space 14″ between or around film stamp 12′ and substrate 13′. A targeted, additional influencing of the demoulding can thus be achieved. In addition, flexible film stamp 12′ can also be relaxed during the demoulding by a slight rear-side overpressure by means of flushing valves 10″, whereas film frame 9′ remains fixed.

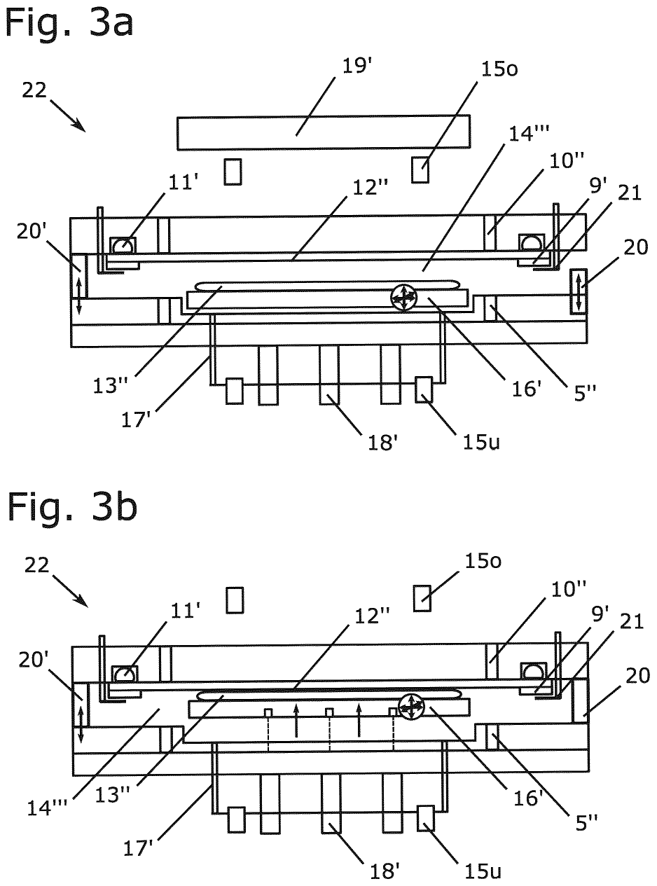

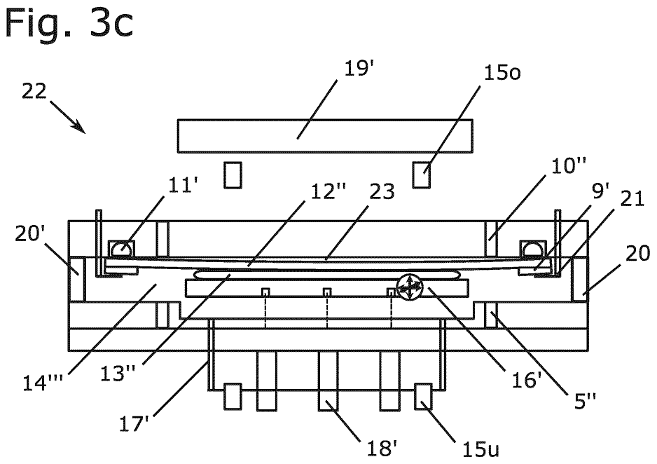

In FIGS. 3a to 3c, the device and the method for the processing are represented as an embossing process in a third embodiment with the film stamp on film frame 9′ above and substrate 13″ below. In the device according to FIGS. 3a to 3c, alignment, embossing, curing and demoulding are preferably carried out in the same module. The device according to FIGS. 3a to 3c has a fixed structure, in which the lower and upper parts of the device, into which the mounting arrangements are integrated, are not separated. The substrate mounting arrangement with adjustment unit 16′ with the mounting surface for mounting substrate 13″ is integrated in the lower part of the device and is dimensioned so as to be as space-saving as possible. A processing space 14″ that is as reduced as possible can thus advantageously be constituted. Spatially bounded and evacuable processing space 14″ around the substrate is defined by gate valves 20, 20′. Gate valves 20, 20′ are loading and unloading openings for a gas-tight closure of the processing space and are each constituted in a wall of the process chamber. The evacuation takes place by means for evacuation 5″, which are arranged on the device in such a way that, after closure of gate valves 20, 20′, processing space 14″ can be evacuated. Substrate 13″ and film stamp 12″ with film frame 9′ are arranged inside processing space 14″′. The processing takes place in the processing space.

In an exemplary embodiment of the method with the device according to FIGS. 3a to 3c, steps c) approach of the upper and/or lower the lower mounting arrangement and d) evacuation/formation of the vacuum in the defined embossing space between the film stamp and substrate, can be arbitrarily exchanged.

The lower substrate mounting arrangement preferably approaches the upper stamp with adjustment unit 16′.

In FIG. 3a, the film stamp with the backplate and with film frame 9′ has already been mounted on the film stamp mounting arrangement. The mounting takes place by means of the film frame loading unit 21 after introduction into the device via a gate valve 20, 20′. The fixing of film frame 9′ takes place by means of fixing elements 11′ and via vacuum track segments distributed in the holding surface of the mounting arrangement, which fix defined the zones of the film rear side (not represented). In particular, structured stamp regions and non-structured regions of the (film) backplate are separated into different vacuum track segments. The film stamp is stretched in a frame, in particular in a film frame 9′.

The substrate can be temporarily stored (not represented) and transferred by means of a handling device (not represented), for example a robot arm, through one of gate valves 20, 20′ into the process chamber onto substrate loading pins 17′. Gate valve 20, 20′ is then closed again. The presence of two gate valves 20, 20′ enables more flexibility in carrying out the process. A gate valve can for example be used for the introduction and removal of substrate 13″, whilst the second gate valve is used for the introduction and removal of film stamp 12″ with film frame 9′. Several substrates and/or different substrates can be embossed with a single film stamp. The film stamp can remain in the device according to FIG. 3a for a plurality of embossing processes.

FIG. 3a shows substrates 13″ coated with embossing lacquer after the mounting on the mounting surface of the mounting body of the substrate mounting arrangement, wherein the loading takes place by loading pin 17′ from above after introduction into the device via a gate valve 20, 20′. Substrate 13″ is fixed by a vacuum or under-pressure via the vacuum tracks. In a preferred embodiment, several vacuum tracks are united to form vacuum track segments, which can be controlled individually, and therefore can be evacuated or flooded (not represented). When substrate 13″ is on the lower mounting arrangement, as represented in the embodiment according to FIG. 3a, the vacuum fixing in another embodiment can be a mechanical fixing for substrate 13″ as an alternative or in addition.

A detection device, in particular with optics 15o, 15u, provides according to an advantageous embodiment for the exact alignment of substrate 13″ and film stamp 12″, whereby it detects the relative positions which it relays to the control unit, which then brings about an alignment of the substrate and the film stamp with one another.

In a first embodiment, film stamp 12″ is aligned relative to substrate 13″, with optical aids 15o, 15u, before the evacuation of embossing space 14″′ is started. A further fine alignment of film stamp 12″ can also take place relative to substrate 13″ after the evacuation of embossing space 14″′. Furthermore, substrate 13″ can also be rotated for example after the evacuation of the processing space 14″′ in order to compensate for a wedge error. This is carried out in particular by means of a WEC 18′, i.e., wedge error compensation.

The distance between substrate 13″ and film stamp 12″ is reduced in the next process step according to FIG. 3b to a precisely defined distance, before the embossing process is started. Preferably, the lower substrate mounting arrangement approaches relative to film stamp 12″.

In the next process step according to FIG. 3c, embossing of the embossing compound takes place by means of film stamp 12″. In a preferred embodiment of the mounting arrangement for the film stamp with the film frame, an inner vacuum segment, which serves as a vacuum fixing, can be switched in such a way that a gas and/or a gas mixture can be pumped via the latter into the intermediate space between the holding surface of the mounting arrangement for the film stamp with the film frame and the film stamp rear side, for the controllable sagging of the film stamp fixed at the edge. The at least one central fixing element can thus be used at the same time as a curvature means after switching over.

The contacting in the device according to FIG. 3b preferably takes place after the approach of the lower substrate mounting arrangement, wherein, as a result of the prestressing of the upper film stamp, only a partial surface of film stamp 12″ is first contacted with substrate 13″ and then an automatic contacting of the contact surfaces is brought about, wherein the entire substrate surface, without repetition of the aforementioned steps, is preferably embossed in an embossing space 14″′ in a vacuum with a thin flexible film stamp.

After full-area contact between the film stamp 12″ and substrate 13″, flexible film stamp 12″ according to FIG. 3c is “released” by an overpressure between the outer holding surface of the film stamp mounting arrangement and film stamp 12″. In the meantime, film stamp frame 9′remains fixed on the film stamp mounting arrangement, so that film stamp 12″ can relax on substrate 13″. The structures are filled with the embossing lacquer by the capillary forces and film stamp 12″ can be adapted to conform to the substrate surface by the flexibility provided at this time. In addition, the Delta of the ambient pressures can be used as an additional external force in order to improve the filling behaviour. The pressure behind film stamp 12″ in film stamp flushing space 23 and the pressure or the vacuum in processing space 14″′ are adjusted in a targeted manner for this purpose. The pressure in processing space 14″′ lies in particular between 1 mbar and 1100 mbar. During the evacuation, the pressure in the processing space is less than 500 mbar, preferably less than 300 mbar, most preferably less than 250 mbar. In particular, a rough vacuum is preferably set between 300 mbar and 1 mbar, most preferably between 250 mbar and 100 mbar.

The pressure in flushing space 23 at the rear side of film stamp 12″ lies in particular between 1 mbar and 1500 mbar. The pressure difference between processing space 14″ and film stamp flushing space 23 (delta of the ambient pressures) lies between 0 and 800 mbar, preferably between 100 and 600 mbar, more preferably between 200 and 600 mbar. A pressure difference of 500 mbar corresponds for example to a force of 4.5 kN, which can be used as an additional force in the embossing process.

UV lamp house 19′ enables the irradiation of the embossing lacquer by means of UV light. In the curing with UV radiation, a temperature control takes place and if need be a temperature compensation. The film stamp material, during the UV curing of the embossing material on the substrate, is preferably at least partially transparent for the wavelength range of the electromagnetic radiation, which crosslinks the embossing material. The optical transparency is in particular greater than 20%, preferably greater than 50%, more preferably greater than 80%, most preferably greater than 95%. The film stamp can also be transparent for other regions of electromagnetic radiation. Other adjoining components of the upper mounting arrangement as well as a section of the upper part of the device, against which UV lamp house 19′ abuts, are or also produced from UV and/or IR transparent materials.

In the last process step (not represented), the demoulding of film stamp 12″ from the embossing compound takes place. At the end of the process, film stamp 12″ is removed in particular from substrate 13″ and substrate 13″ is unloaded. The system preferably comprises sensors for force monitoring for a control of the demoulding step. An adjustment means 16′ for the substrate mounting arrangement is located in the device according to FIG. 3a to 3c, in particular at the underside. The mounting arrangement has in particular six degrees of freedom, three degrees of freedom in translation along the X-, Y-and Z-direction and three degrees of freedom in rotation about the X-, Y-and Z-axis. The degrees of freedom in translation serve for the displacement of the mounting arrangement and thus of substrate 13″ inside the X-Y plane spanned by the X-and Y-direction as well as the movement of substrate 13″ and film stamp 12″ towards one another along the Z-direction. The possibility of rotation about the X-, Y- and Z-axis is used in order to carry out a wedge error compensation (WEC Z-axis 18′) and/or the orientation of substrate 13″ for the demoulding.

### LIST OF REFERENCE NUMBERS

1, 1′, 1″ substrate mounting arrangement, substrate-mounting arrangement
2, 2′, 2″ device for the processing, film stamp mounting arrangement, film stamp-mounting arrangement
3, 3′ substrate-mounting body, substrate holder
4, 4′ film stamp-mounting body
5, 5′, 5″ evacuation means, evacuating means, vacuum line
6, 6′ fixing element(s) for substrate
7, 7′ seal, sealing means
8 actuator (pin)
9,9′ frame, stamp frame, film frame
10, 10′, 10″ flushing means, gas line
11, 11′ fixing element(s) for film frame
12, 12′, 12″ processing means, embossing means, stamp, embossing stamp, flexible film stamp
13, 13′, 13″ substrate, substrate stack
14, 14′, 14″, 14″′ processing space, vacuum-embossing space, space
15, 15o, 15u optics for alignment
16, 16′ adjustment unit (alignment stage)
17, 17′ substrate loading-pins
18, 18′ WEC Z-axis (wedge error compensation)
19, 19′ UV-lamp house
20, 20′ sealing means, gate valve, slide valve (gate valve)
21 loading unit for film frame with film stamp (film frame)
22 processing device, chamber, process chamber, process module
23 flushing space

What is claimed is:

1. A method for processing a substrate, comprising:
providing a substrate mounting arrangement for mounting the substrate,
providing a processing device for the processing of the substrate, the processing device including a flexible film stamp for the processing of the substrate,
forming a local and fluidically tight processing space between the substrate mounting arrangement and the processing device,
evacuating the processing space, and
processing the substrate,
wherein the evacuating of the processing space takes place after the forming of the processing space,
wherein a fluidically tight flushing space between the processing device and the film stamp is flushed in the processing of the substate, and
wherein the processing space and the flushing space are separated from one another fluidically by the film stamp.

2. The method according to claim 1, wherein the forming of the processing space takes place by an approach of the substrate mounting arrangement and the processing device, and
wherein the processing device and the substrate mounting arrangement are aligned with one another before the approach of the substrate mounting arrangement and the device.

3. The method according to claim 1, wherein the forming of the processing space takes place by controllable sealing means.

4. (canceled)

5. The method according to claim 1, wherein a pressure difference between a pressure of the processing space and a pressure of the flushing space is set between 0 and 80000 Pa for the processing.

6. A device for processing a substrate, comprising:
a substrate mounting arrangement for mounting the substrate,
a processing device for processing the substrate,
means for forming of a local and fluidically tight processing space between the substrate mounting arrangement and the processing device,
evacuation means for evacuating the processing space,
processing means for the processing of the substrate, the processing means comprising a flexible film stamp for embossing the substrate, and
flushing means for forming a fluidically tight flushing space between the device and the film stamp, the flushing space being separated fluidically by the film stamp from the processing space,
wherein the film stamp is deformed by the flushing means in a targeted manner.

7. The device according to claim 6, wherein the means for the forming of the processing space are approach means for an approach of the substrate mounting arrangement and the processing device.

8. The device according to claim 7, further comprising:
alignment means for the alignment of the substrate mounting arrangement and the processing device with one another,
wherein the alignment means are constituted such that the substrate mounting arrangement and the processing device are aligned with one another before and/or during an action of the approach means.

9. The device according to claim 8, wherein the substrate mounting arrangement and the processing device comprises corresponding sealing means,
wherein the approach means are constituted such that, after the action of the approach means, the corresponding sealing means form the processing space between the substrate mounting arrangement and the processing device.

10. The device according to claim 6, wherein the means for forming the local and fluidically tight processing space are controllable sealing means for the formation of the processing space between the substrate mounting arrangement and the processing device.

11. The device according to claim 10, wherein the substrate mounting arrangement and the processing device are constituted in one part.

12.-13. (canceled)

14. The device according to claim 6, wherein the processing device is constituted so that a pressure difference between the pressure of the processing space and the flushing space is set between 0 and 80000 Pa.

15. The device according to claim 5, wherein the flushing means are the evacuation means such that, the film stamp is demoulded from the substrate by evacuation of the flushing space.
